(19) United States
(12) Patent Application Publication
(10) Pub. No.: US 2024/0411085 A1
(43) Pub. Date: Dec. 12, 2024

(54) SELECTIVE WAVEGUIDE ION IMPLANTATION TO ADJUST LOCAL REFRACTIVE INDEX FOR PHOTONICS

(71) Applicant: Applied Materials, Inc., Santa Clara, CA (US)

(72) Inventors: Qintao ZHANG, Mt Kisco, NY (US); Eric Jay SIMMONS, Ballston Spa, NY (US); Mayrita ARRANDALE, Santa Clara, CA (US); Judeth Campbell SOUKUP, Saratoga Springs, NY (US); David J. LEE, Poughkeepsie, NY (US); Samphy HONG, Saratoga Springs, NY (US)

(73) Assignee: Applied Materials, Inc., Santa Clara, CA (US)

(21) Appl. No.: 18/208,685

(22) Filed: Jun. 12, 2023

(51) Int. Cl. G02B 6/134; C23C 14/04; C23C 14/48; C23C 14/58; G02B 6/136

(52) U.S. Cl. CPC G02B 6/1347; C23C 14/042; C23C 14/48; C23C 14/5873; G02B 6/136; G02B 2006/12173

(57) ABSTRACT

Disclosed herein are approaches for adjusting local refractive index for photonics IC systems using selective waveguide ion implantation. In one approach, a method may include depositing an optical device film atop a base layer, patterning the optical device film into a plurality of sections, and implanting a first section of the plurality of sections of the optical device film to adjust a refractive index of the first section.

### FIELD OF THE DISCLOSURE

The present disclosure relates to photonic integrate circuit (PIC) processing and, more particularly, to selective waveguide ion implantation to adjust local refractive index for PICs.

### BACKGROUND OF THE DISCLOSURE

It has become more common to route optical signals within optoelectronic devices using waveguides created within a medium housing other circuit components. These devices are known as Photonic Integrated Circuits (PICs), and the passive waveguides are used to route optical signals between active devices on such circuits. Waveguides are also used in such circuits to route optical signals to/from other circuits, usually via fiber ports.

As the density of such PICs increases, so does the need for turns along the path of the waveguides. To avoid radiation loss of the optical signal at the bends, waveguides with high index contrast medium are used. The high index waveguide tightly confines the optical modes in the lateral direction by the large index discontinuity between the waveguide core and the surrounding medium (e.g., dielectric/air). However, because of the tight optical confinement, bending radius and propagation loss are two competing factors such high index contrast waveguides experience.

Therefore, what is needed are ways to adjust localized waveguide refractive index contrast while minimizing propagation loss.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include depositing an optical device film atop a base layer, patterning the optical device film into a plurality of sections, and implanting a first section of the plurality of sections of the optical device film to adjust a refractive index of the first section.

In another aspect, a method for local waveguide tuning may include depositing an optical device film atop a base layer, and patterning the optical device film into a plurality of sections, wherein adjacent sections of the plurality of sections are separated by a gap. The method may further include implanting a first section of the plurality of sections of the optical device film to adjust a refractive index of the first section, wherein a second section of the plurality of sections is not impacted by the implant.

In yet another aspect, a method for local waveguide tuning may include depositing an optical device film atop a base layer, and patterning the optical device film into a plurality of sections, wherein adjacent sections of the plurality of sections are separated by a gap. The method may further include implanting a bending waveguide section of the plurality of sections of the optical device film to adjust a refractive index of the bending waveguide section, wherein a straight waveguide section of the plurality of sections is not impacted by the implant.

### BRIEF DESCRIPTION OF THE DRAWINGS

The accompanying drawings illustrate exemplary approaches of the disclosure, including the practical application of the principles thereof, as follows:

FIG. 1 illustrates a side cross-sectional view of a device including a base layer and an optical device film atop a base layer, according to embodiments of the present disclosure;

FIG. 2 illustrates a side cross-sectional view of the device following patterning of the optical device film, according to embodiments of the present disclosure;

FIG. 3 illustrates a side cross-sectional view of the device during an ion implant to a portion of the optical device film, according to embodiments of the present disclosure;

FIG. 4 illustrates a side cross-sectional view of the device following the ion implant to the portion of the optical device film, according to embodiments of the present disclosure;

FIG. 5 is a graph illustrating various refractive index tuning, according to embodiments of the present disclosure; and

FIG. 6 is a schematic diagram of a system for forming the device, in accordance with embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Integrated circuits (ICs), systems, and methods in accordance with the present disclosure will now be described more fully hereinafter with reference to the accompanying drawings, where various embodiments are shown. The ICs, systems, and methods may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art, embodiments herein provide an ion implantation to enable a flexible a silicon nitride (e.g., Si3N4) photonic platform, wherein the ion implantation enables desired RI (refractive index) adjustment to selective areas.

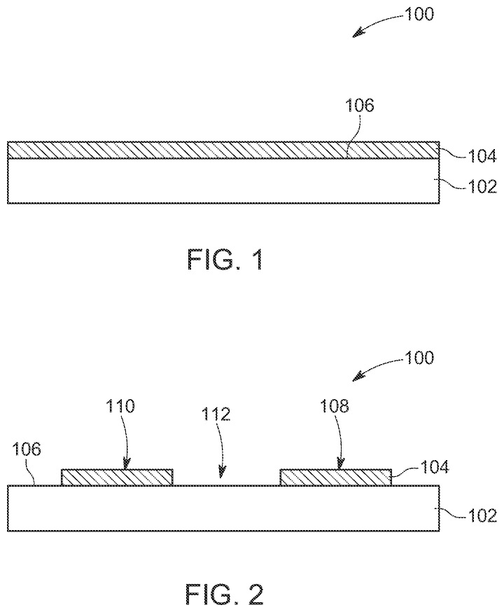

FIG. 1 demonstrates an example photonics IC or device 100 (hereinafter “device”) at one stage of processing. The device 100 may include a base layer 102 formed over a substrate 101, and an optical device film 104 (hereinafter “film”) formed atop an upper surface 106 of the base layer 102. In some embodiments, the base layer 102 may be SiO2, the substrate 101 may be Si, and the film 104 may be silicon nitride (Si3N4), wherein each of the layers are formed using any variety of deposition processes. The film 104 material may be selected to fit one type of application, such as one with a low refractive index for low propagation loss. Although this may be generally beneficial, it is desirable to be able to adjust certain portions of the film 104 in a more efficient manner.

Next, as shown in FIG. 2, the film 104 may be patterned (e.g., etched) by removing one or more sections of the film 104 selective to the upper surface 106 of the base layer 102. Although only a first section 108 and a second section 110 are shown, it will be appreciated that the film 104 may be patterned into a greater number of discreet sections each separated from one another by a gap 112. In the embodiment shown, the first section 108 may be a bending waveguide and the second section 110 may be a straight waveguide. In optical ICs, in order to properly connect various components, it is often necessary to include the straight waveguide and the bending waveguide curved along a surface of the substrate. In the present example, the bending waveguide may include a core that is bent as a curve and a metal cladding enclosing the core, wherein the metal cladding may be formed of a conductive metal material. The outer shape of the metal cladding may the same as the core, but the present disclosure is not limited thereto.

Although not shown in detail, it will be appreciated that one or more lithography and etch steps may be employed to form the first and second sections 108, 110. Because the first section 108 and the second section 110 are formed from the film 104, the first and second sections 108, 110 may be the same material and may have a same thickness relative to the upper surface 106 of the base layer 102. In other embodiments, the film 104 may have multiple sections of different materials, and the first section 108 and the second section 110 are therefore different materials.

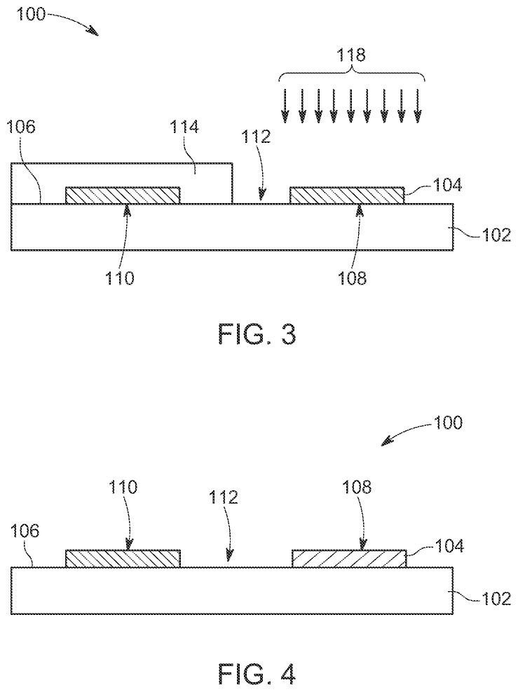

Next, as shown in FIG. 3, a blocking mask 114 may be formed over the second section 110, and an ion species is introduced to the first section 108 as part of an ion implantation process 118. The blocking mask 114 prevents the ion species from impacting the second section 110. Although non-limiting, the ion species may be silicon, (Si), Argon (Ar), Fluorine (F), Nitrogen (N), and others. In some embodiments, the ion implantation process 118 may be performed while the device 100 is at an elevated temperature, e.g., greater than 100° C. It will be appreciated, however, that the ion implantation process 118 may be performed at room temperature or even at a cold temperature (e.g., less than 0° C.). The ion implantation process 118 may involve one or multiple implant steps, performed at a variety of temperatures, implant energies, etc., using one or more ion species.

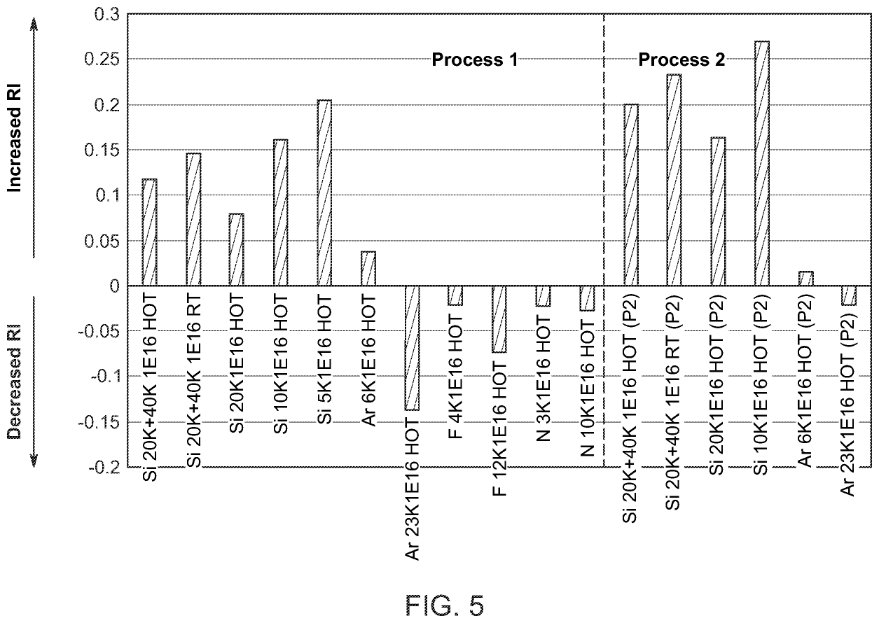

As shown in FIG. 4, following the ion implantation process 118, the RI of the first section 108 may be modified, i.e., increased or decreased. That is, the first section 108 may have a first RI, while the second section 110 may have a second RI, different than the first RI. Furthermore, in some embodiments, the RI may vary across the first section 108 and/or the second section 110. FIG. 5 illustrates possible adjustments to the RI of the first section 108 as a result of the ion implantation process 118. As demonstrated, RI adjustment is dependent upon ion species, implant temperature, implant energy, and others. Although only room temperature (RT) and high-temperature (HOT) implants are shown, it will be appreciated that one or more low-temperature implants may additionally or alternatively be performed. Furthermore, although only Si, Ar, F, and N are identified, other ion species may be considered in alternative examples.

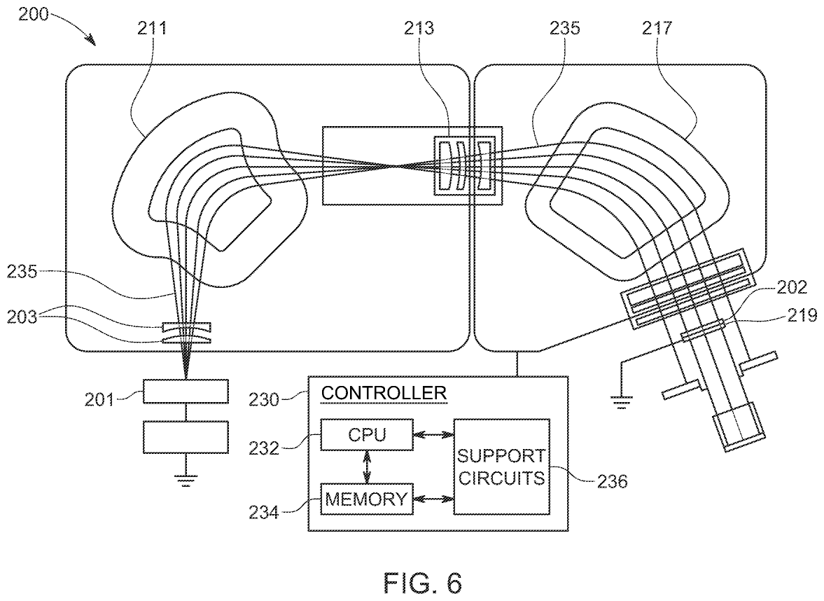

FIG. 6 illustrates a schematic diagram of a processing apparatus 200 useful to perform processes described herein. One example of a beam-line ion implantation processing apparatus is the Varian VIISTA® Trident, available from Applied Materials Inc., Santa Clara, CA. The processing apparatus 200 may include an ion source 201 for generating ions. For example, the ion source 201 may provide an ion implant, such as the ion implantation process 118 demonstrated in FIG. 3. The ion source 201 is operable to perform the ion implantation process 118 at an implant temperature greater than 500° C.

The processing apparatus 200 may also include a series of beam-line components. Examples of beam-line components may include extraction electrodes 203, a magnetic mass analyzer 211, a plurality of lenses 213, and a beam parallelizer 217. The processing apparatus 200 may also include a platen 219 for supporting a substrate 202 to be processed. The substrate 202 may be the same as the base layer 102 described above. The substrate 202 may be moved in one or more dimensions (e.g., translate, rotate, tilt, etc.) by a platform component sometimes referred to as a “roplat” (not shown). It is also contemplated that the platen 219 may be configured to perform the heated ion implantation process 118 described herein.

In operation, ions of the desired species, for example, dopant ions, are generated and extracted from the ion source 201. Thereafter, the extracted ions 235 travel in a beam-like state along the beam-line components and may be implanted in the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to implant desired ions while reducing the probability of undesirable ions (impurities) being implanted in the substrate 202.

In some embodiments, the processing apparatus 200 can be controlled by a processor-based system controller such as controller 230. For example, the controller 230 may be configured to control beam-line components and processing parameters associated with beam-line ion implantation processes. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Implantation and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
depositing an optical device film atop a base layer;
patterning the optical device film into a plurality of sections; and
implanting a first section of the plurality of sections of the optical device film to adjust a refractive index of the first section.

2. The method of claim 1, further comprising forming a mask over a second section of the plurality of sections of the optical device film to protect the second section while the first section is implanted.

3. The method of claim 1, wherein the first section of the plurality of sections is a bending waveguide, and wherein the second section of the plurality of sections is a straight waveguide.

4. The method of claim 1, wherein implanting the first section comprises delivering ions into the first section at a temperature greater than 100° C.

5. The method of claim 1, wherein implanting the first section comprises delivering silicon ions into the first section.

6. The method of claim 1, wherein implanting the first section comprises delivering at least one of the following ion species into the first section: fluorine, argon, and nitrogen.

7. The method of claim 1, wherein depositing the optical device film atop the base layer comprises depositing a silicon nitride film directly atop an upper surface of the base layer.

8. The method of claim 7, wherein patterning the optical device film into the plurality of sections comprises removing one or more sections of the optical device film selective to the upper surface of the base layer.

9. A method for local waveguide tuning, comprising:
depositing an optical device film atop a base layer, wherein the base layer is formed over a substrate;
patterning the optical device film into a plurality of sections, wherein adjacent sections of the plurality of sections are separated by a gap; and
implanting a first section of the plurality of sections of the optical device film to adjust a refractive index of the first section, without implanting a second section of the plurality of sections of the optical device film.

10. The method of claim 9, further comprising forming a mask over the second section of the plurality of sections of the optical device film to block the second section while the first section is implanted.

11. The method of claim 9, wherein the first section of the plurality of sections is a bending waveguide, and wherein the second section of the plurality of sections is a straight waveguide.

12. The method of claim 9, wherein implanting the first section comprises delivering ions into the first section at a temperature greater than 20° C.

13. The method of claim 9, wherein implanting the first section comprises delivering at least one of the following ion species into the first section: silicon, fluorine, argon, and nitrogen.

14. The method of claim 9, wherein depositing the optical device film atop the base layer comprises depositing a silicon nitride film directly atop an upper surface of the base layer.

15. The method of claim 14, wherein patterning the optical device film into the plurality of sections comprises removing one or more sections of the optical device film selective to the upper surface of the base layer.

16. A method for local waveguide refractive index tuning, the method comprising:
depositing an optical device film atop a base layer, wherein the base layer is formed over a substrate;
patterning the optical device film into a bending waveguide section and a straight waveguide section, wherein the bending waveguide section and the straight waveguide section are separated by a gap; and
implanting the bending waveguide section of the optical device film to adjust a refractive index of the bending waveguide section, wherein the straight waveguide section is not impacted by the implant.

17. The method of claim 16, further comprising forming a mask over the straight waveguide section of the optical device film to block the straight waveguide section while the bending waveguide section is implanted.

18. The method of claim 16, wherein implanting the bending waveguide section comprises delivering ions into the bending waveguide section at a temperature greater than 100° C.

19. The method of claim 16, wherein implanting the bending waveguide section comprises delivering at least one of the following ion species into the bending waveguide section: silicon, fluorine, argon, and nitrogen.

20. The method of claim 16, wherein depositing the optical device film atop the base layer comprises depositing a silicon nitride film directly atop an upper surface of the base layer, and wherein patterning the optical device film comprises etching one or more sections of the optical device film selective to the upper surface of the base layer.
